(19) United States
(12) Patent Application Publication
(10) Pub. No.: US 2026/0132502 A1
(43) Pub. Date: May 14, 2026

(54) CONTACTING FINE PARTICLES WITH A GAS PHASE IN A STIRRED BED REACTOR

(71) Applicant: Wacker Chemie AG, Munich (DE)

(72) Inventors: Jan TILLMANN, München (DE); Christoph DRÄGER, München (DE); Michael FRICKE, Burghausen (DE); Alena KALYAKINA, München (DE); Sebastian KNEISSL, Kolbermoor (DE)

(73) Assignee: Wacker Chemie AG, Munich (DE)

(21) Appl. No.: 18/682,134

(22) PCT Filed: Dec. 20, 2021
(86) PCT No.: PCT/EP2021/086901

§ 371 Date: Feb. 8, 2024

(51) Int. Cl. C23C 16/44; B01F 23/30; B01F 101/00; C23C 16/24

(52) U.S. Cl. CPC C23C 16/4417; B01F 23/34; C23C 16/24; B01F 2101/2204; B01F 2215/0409; B01F 2215/0427; B01F 2215/0431; B01F 2215/0468; B01F 2215/0472

(57) ABSTRACT

A process for producing products by contacting particles that are stirred in a fixed bed with a gas phase. Where the particles are treated in a process zone of a gas-traversed reactor where the process zone is the region in a reactor in which the stirred particle bed is brought into contact with the gas phase. The particles are circulated in the process zone by use of a close-clearance stirrer during the contacting with the gas phase and the stirrer mechanism is close-clearance when in equation 1

$$W ( h ) = \frac{{u}_{R} ( h )}{{u}_{B} ( h )} . \qquad ( 1 )$$

The invention relates to a process for producing products by contacting particles in a stirred fixed bed with a gas phase, wherein the treatment of the particles takes place in the process zone of a gas-traversed reactor and the particles are circulated in the process zone by means of a close-clearance stirrer during the contacting with the gas phase, where the stirrer mechanism is close-clearance.

Reactions of gas phases on surfaces of solids are an integral part of the world today. By way of example, treatment of exhaust gas from internal combustion engines takes place on the surface of rhodium catalysts. Many reactions between gases and solid surfaces are also conducted in the chemical industry. To this end, it is generally of great importance that as many solid surfaces as possible can be contacted with a gas so that these reactions can be conducted efficiently and with a high space-time yield. In general, various processes have been developed in the past for bringing solids into contact with a gas. These processes differ primarily in the morphology of the solids used. The technical demands become ever greater the smaller the particles used and the higher the usable solid surface area in the process.

Multiple reactor types are known for commercial application for conducting gas-solid reactions. FBRs (fluidized bed reactors) and rotary kilns, for example, have the disadvantage that they cannot be used for all particle sizes. Especially for very fine particles, reactions with a gas phase are not possible without considerable technical complexitv. Particles of Geldart class C cannot be treated using the available methods. Particles of Geldart class C are characterized by their small size (d₉₀<20 μm) and exhibit strong interparticulate attraction forces, which make clean fluidization difficult. Typical examples are flour or fine dusts, such as abrasion debris from the handling of solids. In slim reactors, these particle beds have a tendency towards the intense formation of bubbles, with lifting of the entire particle bed located above them. In shallow fluidized beds, chimneys or tunnels can form between the distribution base and the bed surface, so that the gas phase no longer flows equally through the other regions of the particle bed [D. Geldart, Types of gas fluidization, Powder Technology 7 (1973) 258]. Good fluidization of such particles can therefore usually only be achieved with mechanical input of energy through stirrers or vibrators.

It is generally known that in multiphase reaction systems comprising at least one bed of particles, good contacting of the porous solid with the fluid precursor is necessary [F. Schüth Chem. Unserer Zeit 2006, 40, 92-103].

An example of such processes that can be described is the production of silicon-carbon composites for use in lithium-ion accumulators.

For example, U.S. Pat. No. 10,147,950 B2 describes the deposition of silicon from monosilane SiH₄ in a porous carbon in a rotary kiln or comparable furnace types at elevated temperatures of 300 to 900° C., preferably with agitation of the particles, by a CVD (“chemical vapor deposition”) or PE-CVD (“plasma-enhanced chemical vapor deposition”) process. A mixture of 2 mol % monosilane with nitrogen is used as inert gas. The low concentration of the silicon precursor in the gas mixture leads to very long reaction times. In addition, the ratio of bed to reactor volume in a rotary kiln is usually very unfavorable, as otherwise there would be a considerable discharge of particles through the gas stream.

A further method for conducting gas-solid reactions is gas-fluidized beds. In a gas-fluidized bed, a bed of solid particles is loosened and borne by an upwardly flowing gas to such an extent that the solid layer as a whole displays liquid-like behavior [VDI-Wärmeatlas [VDI Heat Atlas], 11th edition, Section L3.2 Strömungsformen und Druckverlust in Wirbelschichten [Types of Flow and Pressure Drop in Fluidized Beds, pp. 1371-1382, Springer Verlag, Berlin Heidelberg, 2013].

Gas-fluidized beds are also generally referred to as fluidized beds. The operation of creating a fluidized bed is also referred to as fluidization or fluidizing.

In a gas-fluidized bed, the solid particles are very well-dispersed. Consequently, a very high contact area forms between solids and gas, which can be utilized in an ideal manner for energy and mass transfer processes. Gas-fluidized beds are generally characterized by very good mass and heat transfer operations and by a uniform temperature distribution. The quality of the mass and heat transfer processes is crucial especially for the homogeneity of products obtained by reactions in fluidized beds, and can be correlated with the homogeneity of the fluidization state.

Consequently, the formation of a homogeneous fluidized bed or a homogeneous fluidization state is essential for the use of the fluidized bed process to produce products having the same product properties.

The fluidization properties can be classified depending on the particle size and solid-state density of the particles. Particles having a particle size d₉₀<20 μm and having a density difference between particles and gas >1000 kg/m³ are covered by Geldart class C (cohesive) [D. Geldart, Types of Gas Fluidization, Powder Technology 7 (1973) 285]. Particles of Geldart class C are characterized in that they are difficult to convert to a fluidized state. On account of their small particle size, the influence of interparticulate attraction forces is in the same order of magnitude or greater than the forces that act on the primary particles via the flow of gas. Correspondingly, effects such as the lifting of the fluidized bed as a whole and/or channel formation occur. In the case of channel formation, rather than a fluidized bed, tubes form in the particle bed, through which the fluidizing gas flows preferentially, while there is no flow at all through the majority of the bed. As a result, no homogeneity of fluidization is achieved. If the gas velocity is increased well above the minimum fluidization velocity of the primary particles of the bed, agglomerates consisting of individual particles form with time, and these can be fully or partly fluidized. Typical behavior is the formation of layers with agglomerates of different size. In the lowermost layer, directly above the inflow base, there are very large agglomerates that are moved very little, if at all. In the layer above, there are smaller fluidized agglomerates. The smallest agglomerates are present in the uppermost layer, and these are partly entrained by the gas flow, which is problematic from a process engineering point of view. The fluidization characteristics of such particle beds are additionally characterized by formation of large gas bubbles and low expansion of the fluidized bed. In the English-language literature, this behavior is referred to as “agglomerate bubbling fluidization” (ABF). [Shabanian, J.; Jafari, R.; Chaouki, J., Fluidization of Ultrafine Powders, IRECHE., vol. 4, N.1, 16-50].

It will be clear to the person skilled in the art that ABF fluidized beds, on account of the inhomogeneities within the fluidized bed and the associated inhomogeneous mass and heat transfer conditions, are unsuitable for the production of substances having homogeneous properties.

For this reason, in GB 2580110 B2, for example, particles having a size (d₅₀) of more than 50 μm are fluidized in a fluidized bed with 1.25% by volume of monosilane. However, the thus-obtained particles must be ground to the required target size of <20 μm after the reaction has ended. The fluidization of particles <20 μm would lead in this fluidized bed to intense agglomerations and inhomogeneous infiltration of the porous carbon particles.

Fluidizing aids are known for converting particles <20 μm in the form of agglomerates into a predominantly homogeneous fluidized bed. U.S. Pat. No. 7,658,340 B2 describes, for example, the introduction of further force components such as vibration forces, magnetic forces, acoustic forces, rotational or centrifugal forces or combinations thereof, in addition to the force applied by the fluidizing gas, to influence the size of the agglomerates consisting of SiO₂ nanoparticles (Geldart class C) in the fluidized bed so as to form a predominantly homogeneous fluidized bed.

Cadoret et al. [Cadoret, L.; Reuge, N.; Pannala, S.; Syamlal, M.; Rossignol, C.; Dexpert-Ghys, J.; Coufort, C.; Caussat, B.; Silicon Chemical Vapor Deposition on macro and submicron powders in a fluidized bed, Powder Technol., 190, 185-191, 2009] describe the deposition of silicon from monosilane SiH₄ onto nonporous titanium oxide particles of sub-micrometer size in a vibrated fluidized bed reactor. The vibration input limited the agglomerates to the size range of 300 to 600 μm in the fluidized bed.

Fluidized bed processes without fluidization aids are unsuitable for the intercalation process/deposition process of silicon in porous matrix particles, since particles of a size <20 μm cannot be fluidized homogeneously. Because of the inhomogeneous fluidized bed, homogeneous products cannot be produced.

Fluidized bed processes with fluidization aids are disadvantageous for the contacting of particles of Geldart class C with a gas phase since the fluidization of the particles <20 μm requires a great deal of technical complexity. The additional complexity is associated with high expenditures/costs for investment and maintenance.

A further disadvantage with an exemplary silicon intercalation into porous particles by means of a fluidized bed process with fluidization aids is that the properties of the primary particles, such as the particle density or the surface quality, change over the course of the process. These have an unknown effect on the formation of agglomerates; this formation ought to be known for the process regime. Homogeneous process conditions cannot be guaranteed over the entire duration of the process.

A further disadvantage of fluidized bed technology is that due to the fluidization of the agglomerates consisting of the primary porous particles, gas flows are required, which leads to a discharge of primary particles and/or relatively small agglomerates.

A fundamental disadvantage of fluidized bed technology is that the fluidizing gas stream for formation of a homogeneous fluidized bed depends on the size of the particles or agglomerates in the fluidized bed. As a result, the amount of reactive gas metered in and the contact time of the reactive gas with the porous particles are dependent on the state of fluidization and mixing of the particle bed. By way of example, in the fluidized bed process, the contact time of the gas phase with the particle bed can be increased only by reducing the gas velocitv. However, the gas velocity is the crucial parameter for ensuring the state of fluidization and mixing.

One possibility for solving the disadvantages of fluidized bed technology is to mix the particle bed with the gas phase independently of the flow.

US 2020/0240013 A1 describes the deposition of silicon from a silicon-containing gas onto particles having an average particle size in the lower millimeter range in a stirred bed reactor. Due to the particle size, it can be assumed that the bed material used has very good flowabilitv. With the aid of the apparatus described, the exchange between gas and solid is effected through the use of a central stirring screw, through which the reaction gas is simultaneously fed through openings in the stirred bed. The application document is specifically directed to the advantages of the treatment of particles in the millimeter range, since for particles of this size large fluidizing gas streams are necessary in order to convert the particles into the fluidized state.

However, the stirrer used in US 2020/0240013 A1 is unsuitable for the circulation of cohesive particles <20 μm.

It is known from the technical literature that a very wide variety of stirring means can be used for the circulation of particles in a stirred bed [M. Müller, Feststoffmischen [Solids mixing], Chemie Ingenieur Technik 2007, 79, 7]. By way of example, by using a close-clearance helical stirrer, the particles are transported laterally upwards in the reactor, which results in a circulation stream with relative movement of the particles as a result of material sliding down. Adhesion of the particles to the reactor wall is prevented.

A parameter for describing the state of movement of the particle bed is the Froude number (Fr), which indicates the ratio of centrifugal force to weight force in the rotating system.

$$Fr = \frac{{r}_{c} {ω}^{2}}{g}$$

Here, r_{c} is the characteristic radius relevant to the system. For systems with a rotating mixing mechanism, r corresponds to the outer radius of the stirring means. For systems with a rotating drum, r_{c} is the inner radius of the container. The angular frequency ω=2πn is dependent on the rotational speed n of the rotating system. The influence of the weight force is taken into account via the acceleration due to gravity g. For small Froude numbers, the weight force component predominates, as a result of which the radial transport of material is low. The particle bed is circulated only insufficiently. For large Froude numbers, however, the centrifugal force component dominates, as a result of which the material is conveyed too strongly against the container wall. Here, too, the particle bed is circulated only insufficiently.

One parameter for describing the contact time between the gas phase and the stirred particle bed is the residence time of the gas phase in the reactor. The average residence time tᵥ can be calculated as a quotient of the reactor volume and the volume flow rate of the metered gas phase \dot{V}_{F}:

$${t}_{V} = \frac{{V}_{R}}{{\dot{V}}_{F}}$$

A further important measure for evaluating the homogeneous reaction conditions in the stirred bed reactor is the ratio tᵤ/tᵥ of the circulation time of the particle bed tᵤ to the residence time of the silicon precursor tᵥ. The circulation time tᵤ of the particle bed is calculated as a quotient of the reactor volume V_{R} and the volume flow rate of circulated particles \dot{V}ₚ.

$${t}_{U} = \frac{{V}_{R}}{{\dot{V}}_{P}}$$

The volume flow rate of the particles circulated by the stirring means \dot{V}ₚ is defined as the particle volume displaced in the tangential direction by the stirring means per unit of time and is generally described by the following formula:

$${\dot{V}}_{P} = n 2 π {\sum }_{i} {\int }_{{r}_{R , inner , i}}^{{r}_{R , outer , i}} {r}_{R , i} [ {h}_{o , i} ( r ) - {h}_{u , i} ( r ) ] {dr}_{R , i}$$

The volume flow rate of circulated particles is the product of the rotational speed n and the sum of all tangentially displaced volumes by the individual stirring elements i of the stirring means. The geometric dimensions of each individual stirring element are accounted for by the distance of the inner edge of the stirring means to the axis of rotation r_{R,inner,i}, by the distance of the outer edge of the stirring means to the axis of rotation r_{R,outer,i} and also by the upper contour h_{o.i}(r) and lower contour h_{u.i}(r) of the respective stirring element.

If the ratio tᵤ/tᵥ assumes values <1, the circulation operation of the particles is faster than the flow of a gas through the bed, and there is therefore a uniform distribution of the gas with the particles. For values of the ratio tᵤ/tᵥ>1, the gas flows through the stirred bed faster than the bed itself is circulated. As a result, zones with different deposition conditions form in the stirred bed, which lead to an inhomogeneous product distribution in the bed.

Against this background, the object was to provide a process for the contacting of particles of Geldart class C with a gas phase, said process being technically easy to implement and being devoid of the disadvantages of the above-described prior art processes, in particular in relation to the discharge of particles, the reaction times and the infrastructure required therefor.

The invention provides a process for producing products by contacting particles in a stirred fixed bed with a gas phase,

wherein the treatment of the particles takes place in the process zone of a gas-traversed reactor and the particles are circulated in the process zone by means of a close-clearance stirrer during the contacting with the gas phase, where the stirrer mechanism is close-clearance when in equation 1

$$W ( h ) = \frac{{u}_{R} ( h )}{{u}_{B} ( h )} \qquad ( 1 )$$

for half of all values of h the close clearance W(h) in the process zone W(h) is >0.9, where u_{R}(h)=the outer circumference of the stirrer mechanism in the sectional face at the height coordinate h and u_{B}(h)=the inner circumference of the reactor in the sectional face at the height coordinate h.

Surprisingly, it has been found that as a result of the use according to the invention of a close-clearance stirrer mechanism, particles <20 μm are circulated in a reactor in such a way, and the gas phase is metered in such a way, that the contact time between the gas phase and the solid is of such a duration that a reaction of the gas with the particles is achieved with good conversion, a reaction of the gas at the particles (catalysis) is achieved with good conversion or an efficient physical modification of the particles is achieved.

Compared to the fluidized bed reactor, the gas-traversed stirred reactor, or stirred bed reactor (SBR), has a simpler construction since a smaller amount of gas has to be compressed and preheated in the SBR because the gas is not used for fluidizing. This results in lower costs for the associated assemblies. Complex control and regulation technology for the operation of the fluidizing aids is not necessary in the case of the SBR. Compared to the FBR, the SBR is of smaller build because the stirred bed occupies a smaller volume for a given mass. The specific investment costs are lower.

Compared to GB 2580110 B2, no further process steps are necessary with the process according to the invention.

Compared to the fluidized bed reactor, the particle circulation is independent of the supply of a gas phase. Longer residence times are possible, which inter alia in the case of reactions of the gas phase with the particles lead to higher conversions.

The stirring in the process according to the invention only causes the particles to be circulated. The particles are not swirled up by the stirrer.

The gas stream is dimensioned such that the swirling up of the particles in the process according to the invention by the gas flow is minimal and thus the particle discharge from the reactor is likewise minimal. At the same time, the gas stream is preferably dimensioned such that the conversion, in the case of reactions of the gas phase with the particles, of the gas phase used is maximal or the physical modification of the particles is efficient while simultaneously conserving resources.

Homogeneous contacting conditions of the particles with the gas are possible through suitable choice of the stirrer speed parameter, expressed by the dimensionless Froude number, and through a suitable metering rate.

Compared to US 2020/0240013 A1, the process according to the invention is improved through the use of a close-clearance stirrer.

As a result of this circulation of the particle bed with the close-clearance stirrer, a sufficiently good macromixing of the fluid phase with the solids phase is achieved, which leads to a homogeneous treatment of all particles in the solids phase.

In the case of reactions of the gas phase with the particles, a further economic advantage of the process in contrast to the process not according to the invention consists in a higher conversion of a possible gas phase, for example a higher silicon yield in the case of the deposition of SiH₄ into porous particles.

With the process according to the invention, the covering of particle surfaces with a new functionalization, a reaction of the gas phase with the particles, a reaction of the gas phase at the particles (catalysis) or an efficient physical modification of the particles can for example be conducted with constant circulation of the particle bed by means of a close-clearance stirrer mechanism. The particle bed used can be made up of particles of a single type or of particle mixtures.

The process can also involve performing multiple steps for pre-or post-treatment of the particles used. These treatments can be conducted either in one reactor or in two or more reactors or columns. If gaseous products are obtained from the process, the gas phase conducted out from the process can be separated off from the desired product by a separation, for example by a scrubber, a distillation or a condensation.

If the particles used are pretreated in a separate reactor, the particles can be transferred into a further reactor or container for example by a downpipe, continuous conveyor, flow conveyor/suction or pressure conveying unit (e.g. vacuum conveyor, transport blower); mechanical conveyors (e.g. roller conveyors with drive, screw conveyors, circular conveyors, circulation conveyors, bucket conveyor, rotary star valves, chain conveyors, scraper conveyors, belt conveyors, oscillation conveyors); gravity conveyors (e.g. chutes, roller track, ball track, rail track), and also by means of non-continuous conveyors, floor-based and rail-free (e.g. automated vehicle, manual forklift truck, electric forklift truck), driverless transport systems (DTSs), air-cushion vehicle, hand cart, electric cart, motor vehicle (tractor, wagon, forklift stacker), transfer carriage, transfer/lift carriage, shelf access device (with/without converter, able to follow curved paths); floor-based, rail-bound (e.g. plant railway, track vehicle); floor-free (e.g. trolley track), crane (e.g. bridge crane, portal crane, jib crane, tower crane), electric overhead track, small-vessel transport system; fixed (e.g. elevator, lifting platform and cherry picker, stepwise conveyor).

The close clearance W(h) of a stirrer in a rotationally symmetrical reactor is defined as the quotient of the circumferences of two planar sectional faces perpendicular to the axis of rotation of two surfaces of rotation, with h representing the height coordinate. The inner surface of rotation is formed by a complete revolution of the stirrer mechanism and is characterized by the distance r_{R}(h) from the axis of rotation to the outer contour of the stirrer mechanism. The stirrer mechanism includes all components attached thereto. A planar section at any arbitrary point h of the surface of rotation perpendicular to the axis of rotation forms a circular surface. The circumference of the sectional face is calculated using

$${u}_{R} ( h ) = 2 π {r}_{R} ( h )$$

The outer surface of rotation is formed by rotation of the inner contour of the reactor about the axis of rotation. It is described by the distance r_{B}(h). The inner contour of the reactor includes all components attached thereto. The circumference of an arbitrary sectional face of the outer surface of rotation perpendicular to the axis of rotation is calculated with

$${u}_{B} ( h ) = 2 π {r}_{B} ( h )$$

The close clearance is defined with the aid of the circumferences as follows:

$$W ( h ) = \frac{{u}_{R} ( h )}{{u}_{B} ( h )}$$

In general, a reactor can contain one or more stirrer mechanisms. The contour of each individual stirrer mechanism forms a surface of rotation through a complete revolution. These surfaces of rotation can be present separately. They can preferably overlap one another. If the individual surfaces of rotation or if the overlapping surface of rotation is cut at any point perpendicular to the axis of rotation or axes of rotation, this results in figures or a figure the circumference of which can be ascertained. If multiple figures result, the total circumference is determined by summing the individual circumferences.

In general, the reactor can consist of one or more reactor parts, which are each preferably rotationally symmetrical and connected to one another. The entirety of all reactor walls enclose a figure. If this figure is cut at any point perpendicular to the axis of rotation of the stirrer mechanisms, the circumference of the resulting figure is determinable. The close clearance W(h) is calculated in an analogous manner as for the rotationally symmetrical reactor.

The close clearance can vary with h. An embodiment according to the invention of the stirrer is present when the close clearance W(h) in the process zone for at least half of all values of h is >0.9; W(h_{50%}) is defined for this. In a preferred embodiment W(h_{50%}) is >0.95. In a particularly preferred embodiment W(h_{50%}) is >0.97. In a very particularly preferred embodiment W(h_{50%}) is >0.99. For special cases of the process, values for W(h_{50%})>1 are also possible.

The aim is to keep the dead space of the bed that is not moved by the stirrer as small as possible. The particles at the heated parts of the shell are thus kept in motion as efficiently as possible and the energy is conveyed from the wall into the bed. Adhesion of particles to the wall is also prevented in this way.

A process zone is the region in the reactor in which the stirred particle bed is brought into contact with the gas phase, further defined in that chemical or physical processes, such as drying operations, condensation reactions or decompositions of the gas phase, take place in this region of the reactor.

The gas phase consists of an inert gas and/or optionally at least one reactive component. The one or more reactive components can generally be introduced into the reactor in mixed form or separately or in a mixture with inert gas constituents or as pure substances. The reactive component preferably contains an inert gas constituent of 0% to 99%, particularly preferably at most 50%, especially preferably at most 30% and very particularly preferably at most 5%, based on the partial pressure of the inert gas constituent as a proportion of the total pressure of the reactive component under standard conditions (in accordance with DIN 1343). Examples of inert gas that can be used include hydrogen, helium, neon, argon, krypton, xenon, nitrogen or carbon dioxide or mixtures thereof, such as for example forming gas. Preference is given to argon or in particular nitrogen.

The reactive component can react under the conditions chosen, for example thermal treatment, and is preferably selected from the group containing
hydrogen, oxygen, carbon dioxide, carbon monoxide, dinitrogen monoxide, nitrogen monoxide, nitrogen dioxide, sulfur dioxide
water vapor
hydrides that are gaseous under the conditions chosen, such as SiH₄, GeH₄, SnH₄, SbH₄, GaH₃, AsH₃, BiH₃, NH₃, PH₃, H₂S, H₂Se
oligomeric or polymeric silanes, in particular linear silanes of the general formula SinHₙ₊₂, where n can comprise an integer in the range from 2 to 10, and also cyclic silanes of the general formula —[SiH₂]ₙ—, where n can comprise an integer in the range from 3 to 10
oligomeric or polymeric germanes, in particular linear germanes of the general formula GenHₙ₊₂, where n can comprise an integer in the range from 2 to 10, and also cyclic germanes of the general formula —[GeH₂]ₙ—, where n can comprise an integer in the range from 3 to 10
halogen-containing precursors such as Cl₂, F₂, Br₂, chlorosilanes, phosgene, fluorophosgene, hydrogen chloride, hydrogen bromide, hydrogen fluoride, boron trichloride, boron trifluoride, chlorine dioxide, sulfur hexafluoride, sulfur tetrafluoride, sulfur hexachloride, sulfur tetrachloride, silicon tetrafluoride, trifluorosilane
silicone precursors and precursors for silanization, e.g. silanols and silazanes
examples of possible precursors for polymer coatings from the gas phase include p-xylene or halogenated derivatives thereof, acrylates, methacrylates, poly(tetrafluoroethylene) dispersions, styrene, vinylpyrrolidone, maleic anhydride and others.
hydrocarbons, preferably selected from the group containing aliphatic hydrocarbons having 1 to 10 carbon atoms, preferably 1 to 6 carbon atoms, such as for example methane, ethane, propane, butane, pentane, isobutane, hexane, cyclopropane, cyclobutane, cyclopentane, cyclohexane, cycloheptane; unsaturated hydrocarbons having 1 to 10 carbon atoms, such as for example ethene, acetylene, propene, methylacetylene, butylenes, butynes (1-butyne, 2-butyne), isoprene, butadiene, divinylbenzene, vinylacetylene, cyclohexadiene, cyclooctadiene, cyclic unsaturated hydrocarbons, such as for example cyclopropene, cyclobutene, cyclopentene, cyclohexene, cyclohexadiene, cyclopentadiene, dicyclopentadiene or norbornadiene, aromatic hydrocarbons, such as for example benzene, toluene, p-, m-, o-xylene, styrene (vinylbenzene), ethylbenzene, diphenylmethane or naphthalene, further aromatic hydrocarbons, such as for example phenol, o-, m-, p-cresol, cymene, nitrobenzene, chlorobenzene, pyridine, anthracene or phenanthrene, myrcene, geraniol, thioterpineol, norbornane, borneol, isoborneol, bornane, camphor, limonene, terpinene, pinene, pinane, carene, phenol, aniline, anisole, furan, furfural, furfuryl alcohol, hydroxymethylfurfural, bishydroxymethylfuran and mixed fractions containing a multiplicity of such compounds, such as for example from natural gas condensates, petroleum distillates or coke oven condensates, mixed fractions from the product streams of a fluid catalytic cracker (FCC), steam cracker or a Fischer-Tropsch synthesis plant, or more generally hydrocarbon-containing material streams from wood, natural gas, petroleum and coal processing.

Particularly preferred reactive components are selected from the group comprising hydrogen, oxygen, carbon dioxide, carbon monoxide, monosilane SiH₄, monogermane GeH₄, it being possible for these to be used alone or as mixtures.

During the metering of the gas phase into the reactors, the constituents of the reactive component can be present for example in gaseous, liquid or sublimable solid form.

The reactive component is preferably gaseous, liquid, solid, for example sublimable, or a substance mixture optionally consisting of substances in different states of matter.

In one variant of the process, the gas phase is fed directly into the bed of particles in the reactor, for example from below or from the side or through a special stirrer.

In a preferred embodiment, the temperature, pressure, pressure changes or differential pressure measurements and gas flow measurements in the reactor are determined with established measuring instruments and measurement methods. After standard calibration, different measuring instruments give the same measurement results.

The progress of the treatment of the particles with the gas phase is preferably monitored analytically in order to identify the end of the reaction and thus keep the reactor occupancy time as short as possible. Processes for observing the progress of the reaction include for example temperature measurement for determining exo-or endothermicity to determine the progress of the reaction through changing ratios of solid to gaseous reactor content constituents and further methods which enable observation of the changing composition of the gas space during the reaction. In a preferred variant of the process, the composition of the gas phase is determined by a gas chromatograph and/or thermal conductivity detector and/or an infrared spectroscope and/or a Raman spectroscope and/or a mass spectrometer. In a preferred embodiment, the hydrogen content is determined by means of a thermal conductivity detector and/or any chlorosilanes present are determined by means of a gas chromatograph or gas infrared spectroscope.

In a further preferred variant of the process, the reactor/the position of the gas discharge is equipped with a technical solution for removing condensable or re-sublimable byproducts or products that arise.

In a preferred embodiment of the process, the metering operations are repeated multiple times, where the gas phase respectively being charged can in each case be identical or different, with mixtures of two or more reactive components also being possible. The gas phase charged can in each case likewise be identical or different or consist of mixtures of different reactive components.

As reactors in the context of this application, preference is given to reactor types selected from the group comprising retort ovens, tubular reactors, stirred bed reactors, stirred tank reactors and autoclaves. Particular preference is given to using stirred reactors and autoclaves, especial preference is given to using stirred reactors and very particular preference is given to using stirred tank reactors. These reactors can be operated both at negative pressure and at positive pressure. The reactors used for the process according to the invention must at least be temperature controllable. They can additionally also be vacuum-resistant and pressure-resistant. They can further be equipped with apparatuses for metering and discharging gases, and also apparatuses for introducing and removing solids.

A temperature-controllable reactor is generally a reactor that can be operated such that the temperature in the interior of the reactor can be adjusted for example in the range between −40 and 1500° C. Smaller temperature ranges are possible.

All necessary process steps can be conducted in the reactor according to the invention, but further reactors of a different design can also be used for pre- and post-treatments of the particles.

The particles and a possible resulting particulate, solid product may generally be present during the process as a stationary bed or in an agitated form with mixing. Agitated mixing of the particles or the resulting product is preferred. However, during the contacting of the particles with the gas phases used, the particles must be actively mixed. This makes it possible for example to achieve homogeneous contact of all porous particles with the gas phase or a homogeneous temperature distribution of the bed. The circulation of the particles can be brought about for example by stirring internals in the reactor or by motion of the entire reactor around a stirrer. The bed temperature of the employed particles in the process zone of the reactor equipped with the close-clearance stirrer is preferably in the range from 10 to 2000° C., particularly preferably from 30 to 1500° C. and most preferably from 100 to 1000° C.

A further preferred configuration of the reactors are fixed reactors with moving stirring means for circulation. The purpose of the circulation is to bring the porous solid into contact with the gas phase as uniformly as possible. Preferred geometries therefor are cylindrical reactors, conical reactors, spherical or polyhedral rotationally symmetrical reactors or combinations thereof. The motion of the stirring means is preferably a rotational motion. Other forms of motion are also suitable. The stirring means is preferably driven via a stirrer shaft, where one stirring means or two or more stirring means can be present per stirrer shaft. Two or more stirrer shafts can be introduced into the reactors, on each of which shafts one stirring means or two or more stirring means can be present. The main reactor axis is preferably oriented horizontally or vertically. In a further preferred embodiment, the stirrer shafts are installed horizontally or vertically in a reactor of any desired orientation. For vertically operated reactors, preference is given to configurations in which, for example, one stirring means or two or more stirring means mix the bed material via a rotational movement via a main stirrer shaft. Configurations in which two or more stirrer shafts run in parallel are also possible. Configurations in which two or more stirrer shafts are not operated in parallel to one another are additionally possible. A further configuration for a vertically operated reactor is characterized by the use of a conveying screw. The conveying screw preferably conveys the bed material centrally. A further design according to the invention is the conveying screw rotating along the edge of the reactor. A further preferred configuration is a planetary stirrer system or spiral stirrer system. For horizontally operated reactors, preference is given to configurations in which, for example, one stirring means or two or more stirring means mix the bed material via a rotational movement via a main stirrer shaft. Configurations in which two or more stirrer shafts run in parallel are also possible. Configurations in which two or more stirrer shafts are not operated in parallel to one another are additionally preferred. For vertically operated reactors preference is given to stirring means selected from the group containing helical stirrers, spiral stirrers, anchor stirrers or generally stirring means which convey the bed material axially or radially or both axially and radially and have a close clearance W according to the invention. In horizontally operated reactors, there are preferably two or more stirring means on one shaft. Configurations according to the invention for the stirring means of horizontally operated reactors are plowshare, paddle, blade stirrer, spiral stirrer, or generally stirring means which convey the bed material both axially and radially and have a close clearance W according to the invention. The close clearance can be reduced by additional scrapers on the stirring means. In addition to the moving stirring means, the reactor may also have rigid internals, such as baffles.

Materials suitable for the construction of the reactor for conducting the process according to the invention in principle include any material which exhibits the necessary mechanical strength and chemical resistance under the respective process conditions. In terms of chemical resistance, the reactor may consist both of appropriate solid materials and of chemically non-resistant (pressure-bearing) materials with special coatings or platings of media-contacting parts.

According to the invention, the materials are selected from the group containing:
metallic materials that (according to DIN CEN ISO/TR 15608) for steels correspond to material groups 1 to 11, for nickel and nickel alloys correspond to groups 31 to 38, for titanium and titanium alloys correspond to groups 51 to 54, for zirconium and zirconium alloys correspond to groups 61 and 62 and for cast irons correspond to groups 71 to 76,
ceramic materials of oxide ceramics in the single-substance system, such as, for example, aluminum oxide, magnesium oxide, zirconium oxide, titanium dioxide (capacitor material), and also multi-substance systems, such as, for example, aluminum titanate (mixed form of aluminum oxide and titanium oxide), mullite (mixed form of aluminum oxide and silicon oxide), lead zirconate titanate (piezoceramic), or dispersion ceramics such as aluminum oxide strengthened with zirconium oxide (ZTA—zirconia toughened aluminum oxide)—Al₂O₃/ZrO₂),
non-oxide ceramics, such as, for example carbides, examples being silicon carbide and boron carbide, nitrides, examples being silicon nitride, aluminum nitride, boron nitride and titanium nitride, borides and silicides, and also mixtures thereof, and
composite materials belonging to the groups of the particulate composite materials, such as, for example, cemented carbide, ceramic composites, concrete and polymer concrete, the fiber composite materials, such as, for example, glass fiber-reinforced glass, metal matrix composites (MMC), fiber cement, carbon fiber-reinforced silicon carbide, self-reinforced thermoplastics, steel-reinforced concrete, fiber-reinforced concrete, fiber-plastics composites, such as, for example, carbon fiber-reinforced plastic (CRP), glass fiber-reinforced plastic (GRP) and aramid fiber-reinforced plastic (ARP), fiber-ceramic composites (ceramic matrix composites (CMC)), the penetration composite materials, such as, for example, metal matrix composites (MMC), dispersion-strengthened aluminum alloys or dispersion-hardened nickel-chromium superalloys, the layered composite materials, such as, for example, bimetals, titanium-graphite composite, composite plates and composite tubes, glass fiber-reinforced aluminum and sandwich constructions, and the structural composite materials.

The process is suitable for the manipulation of all particles of Geldart class C. The following list provides only examples and does not limit the scope of the application. The particles used can be porous or nonporous. The particles used for the process according to the invention are preferably selected from the group containing amorphous carbon in the form of hard carbon, soft carbon, mesocarbon microbeads, natural graphite or synthetic graphite, single- and multi-walled carbon nanotubes and graphene, oxides such as silicon dioxide, silica gel, aluminum oxide, silicon-aluminum mixed oxides, magnesium oxide, lead oxides, iron oxides, cobalt oxide, manganese oxide, titanium oxide and zirconium oxide, carbides such as silicon carbides and boron carbides, nitrides such as silicon nitrides and boron nitrides; halides such as aluminum chloride, titanium chloride, magnesium chloride; salts such as carbonates (for example CaCO₃, MgCO₃), sulfates (for example CaSO₄, MgSO₄), sulfides (for example Mo₂S) and other ceramic materials, as may be described by the following component formula:
AlₐB_{b}C_{c}Mg_{d}NₑO_{f}Si_{g} where 0 £ a, b, c, d, e, f, g≤1, with at least two coefficients a to g>0 and a*3+b*3+c*4+d*2+g*4 ³ e*3+f*2.

The ceramic materials can be, for example, binary, ternary, quaternary, quinary, senary or septenary compounds. Preference is given to ceramic materials having the following component formulae:
non-stoichiometric boron nitrides BN_{z} where z=0.2 to 1,
non-stoichiometric carbon nitrides CN_{z} where z=0.1 to 4/3,
boron carbonitrides BₓCN_{z} where x=0.1 to 20 and z=0.1 to 20, where x*3+4 3 z*3,
boron nitridooxides BN_{z}Oᵣ where z=0.1 to 1 and r=0.1 to 1, where 3 ³ r*2+z*3,
boron carbonitridooxides BₓCN_{z}Oᵣ where x=0.1 to 2, z=0.1 to 1 and r=0.1 to 1, where: x*3+4 ³ r*2+z*3,
silicon carbooxides SiₓCO_{z} where x=0.1 to 2 and z=0.1 to 2, where x*4+4 ³ z*2,
silicon carbonitrides SiₓCN_{z} where x=0.1 to 3 and z=0.1 to 4, where x*4+4 ³ z*3,
silicon borocarbonitrides Si_{w}BₓCN_{z} where w=0.1 to 3, x=0.1 to 2 and z=0.1 to 4, where w*4+x*3+4 ³ z*3,
silicon borocarbooxides Si_{w}BₓCO_{z} where w=0.10 to 3, x=0.1 to 2 and z=0.1 to 4, where w*4+x*3+4 ³ z*2,
silicon borocarbonitridooxides SiᵥB_{w}CNₓO_{z} where v=0.1 to 3, w=0.1 to 2, x=0.1 to 4 and z=0.1 to 3, where v*4+w*3+4 ³ x*3+z*2 and
aluminum borosilicocarbonitridooxides AlᵤBᵥSiₓCN_{w}O_{z} where u=0.1 to 2, v=0.1 to 2, W=0.1 to 4, x=0.1 to 2 and z=0.1 to 3, where u*3+v*3+x*4+4 ³ w*3+z*2.

Further particles for the process according to the invention can also be mixed oxides such as titanates (for example barium titanate, lead titanate, strontium titanate, aluminum titanate, perovskite and others) or spinels (for example magnesia spinel, cobalt chromite, cobalt aluminate and others) or tungstates.

Further particles for the process according to the invention can also be substrates with one or more catalytic species, for example nickel, copper, silver, gold, platinum, palladium or rhodium but also metal compounds such as metallocenes. Examples of catalyst supports that can be used include activated carbon, magnesium silicate, aluminum oxide or polymers or silica gels.

Further particles for the process according to the invention can also be of organic nature, for example polymers such as Covalent-Organic Frameworks (COFs), Porous Aromatic Frameworks (PAFs), resins such as resorcinol-formaldehyde resins, melamine-formaldehyde resins, aminophenol-formaldehyde resins, polymers such as Polystyrene, polyvinylpyridine or copolymers thereof or of organometallic nature, for example Metal-Organic Frameworks such as MIL-101 (Cr).

Preferably used as particles are amorphous carbons, silicon dioxide, boron nitride, silicon carbide and silicon nitride or mixed materials based on these materials; particular preference is given to the use of amorphous carbons, boron nitride and silicon dioxide.

The volume-weighted particle size distribution of the particles is determinable according to ISO 13320 by means of static laser scattering using the Mie model with the Horiba LA 950 measuring instrument with ethanol as the dispersing medium for the porous particles.

The particles are preferably in the form of individualized particles. The particles may be present in isolated or agglomerated form for example. The particles are preferably not aggregated and preferably not agglomerated. Aggregated generally means that in the course of the production of the porous particles, primary particles are initially formed and coalesce and/or primary particles are linked to one another, for example via covalent bonds, and in this way form aggregates. Primary particles are generally isolated particles. Aggregates or isolated particles can form agglomerates. Agglomerates are a loose accumulation of aggregates or primary particles that are linked to one another, for example, via van der Waals interactions or hydrogen bonds. Agglomerated aggregates can easily be split back into aggregates again by common kneading and dispersing processes. Aggregates can be broken down into the primary particles only partially by such processes, if at all. The presence of particles in the form of aggregates, agglomerates or isolated particles can be visualized for example using conventional scanning electron microscopy (SEM). By contrast, static light scattering methods for determining particle size distributions or particle diameters of matrix particles cannot distinguish between aggregates and agglomerates.

The particles may have any morphology, i.e. for example, be splintered, flaky, spherical or else needle-shaped, with splintered or spherical particles being preferred. The morphology may, for example, be characterized by the sphericity w or the sphericity S. According to Wadell's definition, the sphericity w is the ratio of the surface area of a sphere of equal volume to the actual surface area of a body. In the case of a sphere, w is 1. According to this definition, the particles for the process according to the invention have a sphericity w of preferably 0.3 to 1.0, particularly preferably of 0.5 to 1.0 and most preferably of 0.65 to 1.0.

The sphericity S is the ratio of the circumference of an equivalent circle with the same area A as the projection of the particle projected onto a surface and the measured circumference U of this projection: S=2\sqrt{πA}/U. In the case of an ideal circular particle, S would have the value 1. For the particles for the process according to the invention, the sphericity S is in the range from preferably 0.5 to 1.0 and particularly preferably from 0.65 to 1.0, based on the percentiles S₁₀ to S₉₀ of the sphericity number distribution. The measurement of sphericity S is carried out for example with reference to micrographs of individual particles with an optical microscope or, in the case of particles <10 μm, preferably with a scanning electron microscope by graphical evaluation using image analysis software such as ImageJ.

If porous particles are used, the porous particles preferably have a gas-accessible pore volume of ≥0.2 cm³/g, particularly preferably ≥0.6 cm³/g and most preferably ≥1.0 cm³/g.

The pores of the porous particles may have any diameter, i.e. generally in the range of macropores (above 50 nm), mesopores (2-50 nm) and micropores (smaller than 2 nm). The porous particles may be used in any mixtures of different pore types. Pore size distribution according to BJH (gas adsorption) in accordance with DIN 66134 in the mesopore range and according to Horvath-Kawazoe (gas adsorption) in accordance with DIN 66135 in the micropore range; the pore size distribution in the macropore range is evaluated by mercury porosimetry according to DIN ISO 15901-1).

The gas-inaccessible pore volume of porous particles can be determined using the following formula:

$$Gas - inaccessible pore volune = 1 / pure - material density - 1 / skeletal density .$$

The pure-material density is a theoretical density of the porous particles, based on the phase composition or the density of the pure substance (density of the material as if it had no closed porosity). Pure-material density data can be found by a person skilled in the art, for example, in the Ceramic Data Portal of the National Institute of Standards (NIST, https://srdata.nist.gov/CeramicDataPortal/scd). For example, the pure-material density of silicon oxide is 2.203 g/cm³, that of boron nitride is 2.25 g cm³, that of silicon nitride is 3.44 g/cm³ and that of silicon carbide is 3.21 g/cm³. The skeletal density is the actual density of the porous particles (gas-accessible) as determined by helium pycnometry.

The process according to the invention can be used for the contacting of all solids according to the invention with gases. The product may be the altered solid and/or part of the exhaust gas from the reactor. Altered solid means that the solid has been chemically or physically altered. It may for example have been oxidized, reduced, calcined, annealed, activated, passivated, coated, infiltrated, dried, cooled or heated. The products produced can be porous or nonporous.

Without limiting the scope of the application, examples of solid products produced include: metal powders, metal oxides, mixed oxides, hydroxides, hydrates, silicon, silicon compounds, silicon microspheres, roasted ores, salts, sulfates, carbonates, chlorides, oxalates, pigments, silicates, aluminum silicates, carbon blacks, organic substances or catalysts.

Typical areas of application for products from the process are batteries, in the tire industry, activated carbon treatment, materials for data transmission and storage, fuel cells, catalysts, clothing, cosmetics, coating materials, solar industry and in the silicon industry.

Products that are discharged with the gas stream from the reactor can be gaseous or liquid under standard conditions.

If a solid is obtained as product via the process according to the invention, the material obtained can have any morphology, for example splintered, flaky, spherical or else needle-shaped, with splintered or spherical particles being preferred.

According to Wadell's definition, the sphericity w is the ratio of the surface area of a sphere of equal volume to the actual surface area of a body. In the case of a sphere, ψ is 1.

The sphericity S is the ratio of the circumference of an equivalent circle with the same area A as the projection of the particle projected onto a surface and the measured circumference U of this projection: S=2\sqrt{πA}/U. In the case of an ideal circular particle, S would have the value 1. The measurement of sphericity S is carried out for example with reference to micrographs of individual particles with an optical microscope or, in the case of particles smaller than 10 μm, preferably with a scanning electron microscope by graphical evaluation using image analysis software such as ImageJ.

An example of the use of the process according to the invention is the coating of particles of Geldart class C. This process is based on chemical vapor deposition (CVD), in which a gaseous reactive component is chemically decomposed on the surface of a particle and thus forms a film on the surface of the particle. The coating of solids is an essential process for a multiplicity of industries, including chemicals, pharmaceuticals, agriculture, cosmetics, electronics and food. Coatings are used for a multiplicity of purposes, in order to control the release or dissolution of active ingredients, to improve the flowability of powders, to protect reactive substances that are susceptible to oxidation, light, air or moisture, to improve mechanical properties (e.g. abrasion resistance and compressibility) or to improve the esthetic appeal (e.g. texture, appearance, odor and taste masking, color).

Polymer coatings can be obtained using this process. In this case, vapor phase monomers react to form pure solid films directly on a surface. Polymerization and coating are thus effected in a single processing step. This enables the formation of highly crosslinked coatings which for example cannot be produced using other processes on account of incompatible monomers. A known gap in the application of CVD processes is the modification of surfaces with polymers with limited to no solubility, as is the case for example with poly(tetrafluoroethylene) (PTFE) and many other fluoropolymers, electrically conductive polymers and highly crosslinked organic networks.

As an undesirable side reaction in the CVD process, the formation of particles from the gas phase (homogeneous deposition) can also take place. Typically, the homogeneous deposition takes place at the hottest points of the reactor and will be more pronounced in reactors having a high temperature gradient.

However, these undesirable side reactions can be avoided if the particles are constantly in motion, as is the case in the stirred bed reactor according to the invention. This motion leads to high heat transport, which minimizes the temperature gradient in the reactor. In addition, the caking of the particles on the reactor walls is suppressed.

Further examples of the use of the stirred bed reactor according to the invention can include any chemical reactions of fine particles of Geldart class C with a gas phase. Examples of such chemical reactions can include:
etching
carbonization and calcination
reduction or oxidation reactions
functionalization of solids such as for example halogenation, alkylation, nitration, hydroformylation, silanization
gas-gas reactions over a stirred catalyst, such as for example the production of hydrogen from water vapor at a surface of a metal oxide
surface treatments such as activation, passivation and cleaning
physical processes such as for example drying, including supercritical drying, annealing
gas-solid reactions with solid or gaseous products, such as for example heterogeneously catalyzed chemical reactions. One example of such reactions can also be the production of polyethylene by means of the Ziegler-Natta process.

In heterogeneously catalyzed reaction systems, that is to say when reactants from the gas phase are to be reacted on the surface of a solid catalyst, in addition to good mass and heat transfer between particles and the surrounding gas phase there is also very good macroscopic energy transport between the particle bed and the reactor wall. The constant motion of the particles and the circulation of the entire particle bed leads to high heat transport, as a result of which hot spots are avoided and the entire bed only has weak temperature gradients.

A further example of the application of the process according to the invention in the stirred bed reactor can be the production of core-shell structures proceeding from particles of Geldart class C which can be used for example as separating agents for HPLC and UHPLC columns. Columns packed with core-shell particles deliver markedly higher efficiency than columns packed with fully porous particles of the same diameter. These particle structures can be produced in an advantageous manner via the process according to the invention.

The products produced can be analyzed using suitable established analytical methods, for example NMR (nuclear magnetic resonance), EA (elemental analysis), IR (infrared spectroscopy), Raman spectroscopy, X-ray diffraction, SEM (scanning electron microscopy), qualitative analysis, quantitative analysis, electrogravimetry, conductometry, potentiometry, polarography, particle size determination, surface characterizations, chromatography, mass spectrometry, density determinations, nitrogen sorption, thermogravimetry, calorimetry, ICP emission spectroscopy, volumetry, spectrophotometry, ion chromatography.

The following analytical methods and instruments were used for characterization:

### Inorganic Analysis/Elemental Analysis:

The C contents reported in the examples were determined with a Leco CS 230 analyzer; for determination of O and optionally N or H contents a Leco TCH-600 analyzer was used. The qualitative and quantitative determination of other reported elements was carried out by ICP (inductively coupled plasma) emission spectrometry (Optima 7300 DV, Perkin Elmer). To this end the samples were subjected to acid digestion (HF/HNO₃) in a microwave (Microwave 3000, from Anton Paar). The ICP-OES determination is based on ISO 11885 “Water quality-Determination of selected elements by inductively coupled plasma optical emission spectrometry (ICP-OES) (ISO 11885:2007); German version of EN ISO 11885:2009”, which is used for analysis of acidic aqueous solutions (for example acidified drinking water, wastewater, and other water samples and aqua regia extracts of soils and sediments).

### Particle Size Determination:

The particle size distribution was determined in the context of this invention in accordance with ISO 13320 by static laser scattering using a Horiba LA 950. In the preparation of the samples, particular care must be taken in dispersing the particles in the measurement solution in order to ensure that what is measured is the size of individual particles and not that of agglomerates. The particles were dispersed in ethanol for the measurement. To this end, prior to measurement the dispersion was treated if required with 250 W ultrasound for 4 min in a Hielscher UIS250v laboratory ultrasound instrument with LS24d5 sonotrode.

### BET Surface Area Measurement:

The specific surface area of the materials was measured via gas adsorption with nitrogen using a Sorptomatic 199090 instrument (Porotec) or SA-9603MP instrument (Horiba) by the BET method (determination in accordance with DIN ISO 9277:2003-05 using nitrogen).

### Skeletal Density:

The skeletal density, i.e. the density of the porous solid based on the volume of only the externally gas-accessible pore spaces, was determined by He pycnometry in accordance with DIN 66137-2.

### Gas-Accessible Pore Volume:

The Gurwitsch gas-accessible pore volume was determined by gas sorption measurements with nitrogen in accordance with DIN 66134.

### Conversion:

The conversion is calculated for example as the quotient of the amount of substance in mol of the converted starting material relative to the amount of substance in mol of the employed starting material (reactant). In these examples it indicates how much of the SiH₄ molecules used are converted to Si.

$$Conversion of {SiH}_{4} in \% = \frac{amount of substance of obtained Si}{amount of substance of employed {SiH}_{4}} * 100 \%$$

### Yield:

The yield is the quotient of the mass of product actually obtained and the theoretical maximum possible product mass. The yield is expressed as a mass ratio quantity in percent:

$$Yield in \% = \frac{Actual mass of product}{Maximum possible mass of product} * 100 \%$$

It is a measure of the losses of particles entrained by the gas stream.

### EXAMPLES

The SiH₄ used, of quality 4.0, was obtained from Linde GmbH.

In all of the examples, the amorphous porous carbon was used as porous particles:
spec. surface area=1907 m²/g
pore volume=0.96 cm²/g
median volume-weighted particle size D50=2.95 μm
particle density=0.7 g/cm²
cohesive, classified as Geldart class: C

### Conversion Calculation for the Examples

The conversion is calculated as the quotient of the amount of substance in mol of the converted starting material relative to the amount of substance in mol of the employed starting material (reactant). In these examples it indicates how much of the SiH₄ molecules used are converted to Si.

$$Conversion of {SiH}_{4} in \% = \frac{amount of substance of obtained Si}{amount of substance of employed {SiH}_{4}} * 100 \%$$

### Yield Calculation for the Examples

The yield is the quotient of the mass of product actually obtained and the theoretical maximum possible product mass. The yield is expressed as a mass ratio quantity in percent:

$$Yield in \% = \frac{Actual mass of product}{Maximum possible mass of product} * 100 \%$$

It is a measure of the losses of particles entrained by the gas stream.

The following reactors were used when conducting the experimental examples:

The reactor used for all examples 1 to 5 according to the invention consisted of a cylindrical lower part (beaker) having an internal radius r_{B}=121.5 mm and a height h=512 mm and of a lid having multiple connections (for example, for gas supply, gas discharge, temperature measurement and pressure measurement) and of a flat base. Internals on the wall were not present. The volume of the reactor was V_{B}=24I. The circumference of an arbitrary sectional face of the surface of rotation produced by rotation of the inner reactor contour about the axis of rotation is calculated as 763.4 mm. The stirrer used was a multi-flight helical stirrer having a radius of r_{R}=119.5 mm. Complete revolution of the helical stirrer produces a surface of rotation. The circumference of an arbitrary sectional face perpendicular to the axis of rotation of this surface of rotation is 750.8 mm. From the two circumferences, a close clearance of W=0.98 is obtained. The height of the helix corresponded to around 75% of the clear height of the reactor interior. The reactor was filled such that the height of the stirred particle bed is lower than the height of the helix. Accordingly, more than 50% of the process zone is in the region of the stirrer having the close clearance W=0.98. The beaker was heated electrically with a jacket heater. The temperature was measured in principle between the heater and the reactor. The gas was supplied in the lower half (125 mm above the reactor base) of the bed, via two submerged tubes having an outer diameter of d=6 mm, which introduced the gas directly into the moving bed.

The fluidized bed reactor used in comparative example 1 (not in accordance with the invention) consisted of a cylindrical part having an outer diameter of 160 mm and a height of 1200 mm. The cylindrical part was composed of a bottom chamber and the fluidized bed reactor itself. The two parts were separated from one another by the gas-permeable base. The cylindrical reactor part was followed at the top by a reactor part with cross-sectional widening to twice the cross-sectional area by comparison with the cylindrical reactor part. At the top end of the reactor there was a lid with filter elements for the exit of gas. The reaction temperature was adjusted via heating of the reactor wall, with the height of the heated region being 80% of the cylindrical length beginning at the gas-permeable base. The measure used for the process temperature was the temperature between heating jacket and reactor outer wall. Heating was effected electrically. The fluidizing gas was accordingly preheated with a gas heater prior to flowing into the fluidized bed reactor. The fluidizing gas stream was pulsed using a directly controlled solenoid valve. As a measure of the quality of the fluidized bed, the fluidization index was employed.

In preliminary tests, the minimum fluidization velocity was determined by measuring the pressure drop of the fluidized bed.

Definition of fluidization index: The fluidization index F/is defined as the ratio of the pressure drop measured over the fluidized bed Δp_{WS,measurement} to the theoretical maximum attainable pressure drop Δp_{WS,th} and is calculated by the following equation 1:

$$FI = \frac{Δ {p}_{WS , measurement}}{{Δp}_{WS , th}}$$

The theoretical maximum attainable pressure drop is calculated, disregarding the gas density, from the mass of the bed m_{S}, the acceleration due to gravity g and the reactor cross-sectional area A_{WS}, as Δp_{WS,th}=mₛ·g/A_{WS}.

In the case of a completely fluidized bed, the fluidization index adopts values of not more than 1.

Determination of the fluidization index: The fluidization index is the ratio of measured pressure drop to theoretical maximum possible pressure drop. For determining the fluidization index, it is necessary to detect the pressure drop of the fluid bed by technical measurement. The pressure drop is measured as a differential pressure measurement between bottom and top ends of the fluidized bed. The differential pressure measurement instrument converts the pressures detected on membranes into digital values and displays the pressure difference. The pressure measurement lines must be configured such that they are arranged directly above the gas-permeable base and directly above the fluidized bed. For the determination of the fluidization index, the precise detection of the weight of the particle bed introduced is additionally necessary. See also [VDI-Warmeatlas [VDI Heat Atlas], 11th edition, section L3.2 Strömungsformen und Druckverlust in Wirbelschichten [Types of Flow and Pressure Drop in Fluidized Beds], pp. 1371-1382, Springer Verlag, Berlin Heidelberg, 2013].

Determination of the minimum fluidization velocity: The minimum fluidization velocity is the fluidizing gas velocity—based on the empty reactor cross-sectional area—at which the particle bed transitions from the flow-traversed fixed bed into a fluidized bed. The minimum fluidization velocity can be determined through simultaneous measurement of the regulated fluidizing gas stream, using a mass flow meter, and of the pressure drop of the fluidized bed, using a digital differential pressure meter. Given knowledge of the cross-sectional area of the reactor, the fluidizing gas velocity can be calculated from the fluidizing gas stream measured. The plotted profile of the pressure drop against the fluidizing gas velocity is referred to as the fluidized bed characteristic curve. It should be noted that the fluidized bed characteristic curve is recorded, starting from a high fluidizing gas velocity, by gradual reduction of this velocity. In the case of a pure fixed bed traversing flow, the pressure drop increases linearly. The associated fluidization index FI is less than one. For a fully developed fluidized bed, the pressure drop measured is constant. The associated fluidization index FI is equal to one. The state of minimum fluidization is situated at the transition between the two regions. The associated fluidizing gas velocity, based on the empty reactor cross-sectional area, is equal to the minimum fluidization velocity. If the transition from the fixed bed to the fluidized bed is characterized by a range, the point of intersection of the extrapolated fixed bed characteristic curve and the extrapolated fluidized bed characteristic curve is defined as the point of minimum fluidization. See also [VDI-Warmeatlas [VDI Heat Atlas], 11th edition, section L3.2 Strömungsformen und Druckverlust in Wirbelschichten [Types of Flow and Pressure Drop in Fluidized Beds], pp. 1371-1382, Springer Verlag, Berlin Heidelberg, 2013]. In comparative example 2 (not in accordance with the invention), an indirectly heated rotary kiln was used. This rotary kiln possessed a rotary tube made of quartz glass, rotatable about its longitudinal axis, having a diameter of 20 cm and a heatable volume of 30 L. The outer wall temperature of the quartz tube was used as a measure of the process temperature. Heating was effected electrically and could be regulated through 3 zones. For the implementation of the silicon infiltration reactions, the rotary tube ought to be sealed gastight.

### Comparative Example 1 (not in Accordance with the Invention): Production of a Silicon-Containing Material in a Fluidized Bed Reactor with Pulsed Fluidizing Gas Stream

500 g of an amorphous carbon as porous starting material (specific surface area=1907 m²/g, pore volume=0.96 cm³/g, median volume-weighted particle size D₅₀=2.95 μm, particle density=0.7 g/cm³, particles of Geldart class C) were introduced into the reactor.

The particle bed was fluidized with a fluidizing gas consisting of nitrogen, the quantity of gas being such that the minimum fluidization velocity was at least 3 times that ascertained in the preliminary tests. At the same time, using the solenoid valve, the gas stream was induced to oscillate, with the frequency between the open and closed positions of the valve being 3 Hz. The temperature in the reactor was then raised to the setpoint temperature of 430° C. On account of the rise in temperature, the fluidizing gas stream was adapted such that the fluidization index adopted a value >0.95.

On attainment of the setpoint temperature of 430° C., the fluidizing gas was replaced by reactive gas containing 10% by volume of SiH₄. The pulsation of the gas stream with the frequency between the open and closed positions of the valve of 3 Hz was maintained during and after the switch of the fluidizing gases, and, in addition, not only the values for the fluidization index of FI=0.98 but also, owing to the change in density of the porous starting materials during the deposition of the silicon, the gas quantity of the fluidizing gas were adjusted in such a way that the fluidization index values were always greater than 0.95.

After a reaction time of 2.6 hours, the fluidizing gas was switched back to a pulsed stream of nitrogen. The heating power was reduced. When a temperature of 50° C. was reached, the fluidizing gas stream was changed over to a fluidizing gas consisting of 5% by volume of oxygen in nitrogen and was maintained for 60 min in order to allow for controlled reaction of any reactive groups present on the surface of the product obtained. The reactor was subsequently cooled down to room temperature.

After the ending of the operation, 990 g of a black solid were discharged from the reactor. The silicon-containing material obtained was introduced into a cylindrical vessel and homogenized in a drum hoop mixer. The agglomerates formed as a result of the fluidized bed process could be eliminated by sieving. The reaction conditions for the production and also the material properties of the silicon-carbon composite particles are summarized in table 2.

### Comparative Example 2 (not in Accordance with the Invention): Production of a Silicon-Containing Material by a Process not in Accordance with the Invention in the Rotary Tubular Reactor

A rotary tubular reactor (internal volume 30 L) was charged with 0.9 kg of the same porous carbon as in comparative example 1 (specific surface area=1907 m²/g, pore volume=0.96 cm³/g, median volume-weighted particle size D₅₀=2.95 μm, particle density=0.7 g/cm³, particles of Geldart class C). After inertization with nitrogen, the reactor was heated to 430° C. When the reaction temperature was reached, the reactive gas (10% SiH₄ in N₂, metering rate 2.3 m³/h) was passed through the reactor for 8.5 h, during which the reactor was rotated at a speed of around 7 revolutions per minute. The reactor was subsequently purged with inert gas. Before the product was withdrawn from the reactor, it was cooled to room temperature under inert gas. The reaction conditions for the production and also the material properties of the silicon-carbon composite particles are summarized in table 2.

### Examples 1-5 (According to the Invention): Production of Silicon-Containing Materials by the Process According to the Invention Using Monosilane SiH₄ as Silicon Precursor Under Standard Pressure (0.1 MPa) (the Respective Values for the Parameters A-D and Also the Example Number are Summarized in Table 1)

2.4 kg of the same porous carbon as in comparative examples 1 and 2 (specific surface area=1907 m²/g, pore volume=0.96 cm³/g, median volume-weighted particle size D₅₀=2.95 μm, particle density=0.7 g/cm³, particles of Geldart class C) were introduced into the reactor according to the invention with the stirrer mechanism (volume 24 L, diameter 25 cm). The temperature of the reactor was subsequently adjusted to 350° C. for 240 minutes and the reactor was inertized with nitrogen.

The reactor was subsequently heated to 430° C. When the reaction temperature was reached, the reactive gas was passed through the reactor with concentration A and metering rate B for C hours. The gas phase was supplied to the reactor, while the particle bed was circulated by a close-clearance stirrer mechanism according to the invention, a helical stirrer, such that the ratio of circulation time to the average residence time of reactive component was D and the state of motion of the bed could be described by Froude number 3.

Subsequently, the silicon-containing material was cooled within 120 minutes to a temperature of 70° C. The reactor was subsequently purged for one hour with nitrogen, for one hour with lean air having an oxygen content of 5% by volume, for one hour with lean air having an oxygen content of 10% by volume, for one hour with lean air having an oxygen content of 15% by volume, and subsequently for one hour with air. Lastly, the product was withdrawn from the reactor.

TABLE 1
Experimental parameters for Examples 1 to 5 according to the invention

| Experimental | | Example number | | | | |
|---|---|---|---|---|---|---|
| parameters | Designation | Ex 1 | Ex 2 | Ex 3 | Ex 4 | Ex 5 |
| SiH₄ conc., mol % | A | 10 | 50 | 50 | 100 | 100 |
| Metering rate, m³/h | B | 6.1 | 1.2 | 4.6 | 0.6 | 0.3 |
| Duration of SiH₄ | C | 9.7 | 6.9 | 2.5 | 5.3 | 8.5 |
| addition, h | | | | | | |
| Ratio of t | D | 0.075 | 0.015 | 0.015 | 0.007 | 0.007 |
| circulation time/t | | | | | | |
| residence time | | | | | | |

The reaction conditions for production and the material properties of the silicon-carbon composite particles are summarized in the following table 2.

TABLE 2

| | Comp ex 1* | Comp ex 2* | Ex 1 | Ex 2 | Ex 3 | Ex 4 | Ex 5 |
|---|---|---|---|---|---|---|---|
| Reactor type | Fluidized bed | Rotary kiln | SBR | SBR | SBR | SBR | SBR |
| | pulsed | | | | | | |
| Amount of reactant, kg | 0.5 | 0.9 | 2.4 | 2.4 | 2.4 | 2.4 | 2.4 |
| SiH₄ conc., mol % | 10 | 10 | 10 | 50 | 50 | 100 | 100 |
| Jacket temperature | 430 | 430 | 430 | 430 | 430 | 430 | 430 |
| during SiH₄ addition, ° C. | | | | | | | |
| Duration of the SiH₄ | 2.6 | 9.9 | 9.7 | 6.9 | 2.5 | 5.3 | 8.5 |
| addition, h | | | | | | | |
| Reactor volume, L | 20 | 30 | 24 | 24 | 24 | 24 | 24 |
| Reactor diameter, m | 0.15 | 0.20 | 0.25 | 0.25 | 0.25 | 0.25 | 0.25 |
| Fr number | n.a. | 0.005 | 3 | 3 | 3 | 3 | 3 |
| Ratio of t circulation | n.a. | n.a. | 0.075 | 0.015 | 0.015 | 0.007 | 0.007 |
| time/t residence time | | | | | | | |
| Conversion of SiH₄, % | 20 | 40 | 41 | 60 | 40 | 75 | 98 |
| Amount of product, kg | 0.99 | 1.84 | 5.67 | 5.74 | 5.51 | 5.66 | 5.80 |
| Product yield, % | 80 | 82 | 95 | 96 | 92 | 95 | 97 |
| Particle discharge | yes | yes | no | no | no | no | no |
| Si, % by weight | 56 | 56.5 | 56 | 57 | 55 | 56 | 57 |
| O, % by weight | 3.8 | 3.04 | 2.1 | 2.64 | 3.62 | 2.64 | 2.84 |
| BET m²/g | 11 | 10 | 23 | 26.6 | 43.6 | 26.8 | 23.8 |

*not in accordance with the invention

Regardless of the reactors used, the same characteristic material properties can be obtained. However, SiH₄ conversion, product yield and reaction time in the reactor system according to the invention were improved compared to fluidized beds and rotary kilns.

1-7. (canceled)

8. A process for producing products, comprising:
contacting particles of Geldart class C having a particle size d₉₀<20 μm in a stirred fixed bed with a gas phase;
treating the particles in a process zone of a gas-traversed reactor, wherein the process zone is the region in a reactor in which the stirred particle bed is brought into contact with the gas phase; and
circulating the particles in the process zone by use of a close-clearance stirrer during the contacting with the gas phase,
wherein the stirrer mechanism is close-clearance when in equation 1
$$W ( h ) = \frac{{u}_{R} ( h )}{{u}_{B} ( h )} \qquad ( 1 )$$
wherein for half of all values of h the close clearance W(h) in the process zone W(h) is >0.9,
wherein u_{R}(h) is equal to the outer circumference of the stirrer mechanism in the sectional face at the height coordinate h, and
wherein u_{B}(h) is equal to the inner circumference of the reactor in the sectional face at the height coordinate h.

9. The process of claim 8, wherein the process zone of the reactor is rotationally symmetrical;
wherein the stirrer mechanism is close-clearance when in equation 1
$$W ( h ) = \frac{{u}_{R} ( h )}{{u}_{B} ( h )} ; \qquad ( 1 )$$
wherein W(h) is equal to the close clearance of a stirrer mechanism in a rotationally symmetrical reactor, defined as the quotient of the circumferences of two planar sectional faces perpendicular to the axis of rotation of two surfaces of rotation, with h representing the height coordinate;
wherein u_{R}(h) is equal to the circumference of the inner sectional face of the circular inner sectional face calculated according to equation 2
$${u}_{R} ( h ) = 2 π {r}_{R} ( h ) ; \qquad ( 2 )$$
wherein at a plurality of arbitrary points h of the surface of rotation perpendicular to the axis of rotation through a planar section;
wherein r_{R}(h) is equal to the distance from the axis of rotation to the outer contour of the stirrer mechanism, wherein the stirrer mechanism includes all components attached thereto;
wherein u_{B}(h) is equal to the circumference of the outer surface of rotation of the circular outer surface of rotation calculated according to equation 3
$${u}_{B} ( h ) = 2 π {r}_{B} ( h ) ; \qquad ( 3 )$$
wherein at each arbitrary point h of the surface of rotation perpendicular to the axis of rotation through a planar section, said circular outer surface of rotation being formed by rotation of the inner contour of the reactor about the axis of rotation;
wherein r_{B}(h) is equal to the distance of the inner contour of the reactor to the axis of rotation; and
wherein for half of all values of h the close clearance W(h) in the process zone W(h) must be >0.9.

10. The process of claim 8, wherein the contacting of the particles with the gas phase takes place at 0.08 to 5 MPa.

11. The process of claim 8, wherein the bed temperature in the process zone of the reactor equipped with the close-clearance stirrer is in the range from 30 to 1500° C.

12. The process of claim 8, wherein the process is conducted in two or more interconnected reactors.

13. The process of claim 8, wherein chemical or physical processes take place in the process zone of the reactor.

14. The process of claim 13, wherein the chemical processes are selected from covering of particle surfaces with a new functionalization, a reaction of the gas phase with the particles and a reaction of the gas phase at the particles.
